(19) United States
(12) Patent Application Publication
(10) Pub. No.: US 2007/0291882 A1
(43) Pub. Date: Dec. 20, 2007

(54) APPARATUS AND METHOD FOR DETECTING SIGNAL IN MULTI-INPUT MULTI-OUTPUT SYSTEM

(75) Inventors: Sung-Woo Park, Suwon-si (KR); Joo-Hyun Lee, Suwon-si (KR); Kyung-Joo Suh, Seoul (KR); Young-Hoon Kwon, Seongnam-si (KR); Sung-Soo Hwang, Yongin-si (KR); Jong-In Kim, Suwon-si (KR); Joon-Hyuk Kang, Seoul (KR); Jong-Sub Cha, Seoul (KR)

Correspondence Address: Jefferson IP Law, LLP, 1730 M STREET, NW, SUITE 807, WASHINGTON, DC, 20036, US

(73) Assignees: Samsung Electronics Co., LTD., Suwon-city (KR); Research and Industrial Cooperation Group, Daejeon (KR)

(21) Appl. No.: 11/762,265

(22) Filed: Jun. 13, 2007

(30) Foreign Application Priority Data
Jun. 15, 2006 (KR) 10-2006-0053867

(51) Int. Cl. H04L 1/02; H03D 1/00

(52) U.S. Cl. 375/347; 375/341

(57) ABSTRACT

A signal detection apparatus and method using a modified stack algorithm in a Multi-Input Multi-Output (MIMO) system are provided. The signal detection method includes sorting signals received via antennas and channel coefficients for respective users in descending order, decomposing a channel matrix composed of the sorted channel coefficients into a unitary matrix and an upper-triangular matrix, determining the number of candidate symbol-sequences using the decomposed upper-triangular matrix, obtaining a signal vector for the antennas by using the sorted signals received via respective antennas and the unitary matrix, wherein the signal vector is proportional to the upper-triangular matrix, and detecting the determined number of candidate symbol-sequences by using a modified stack algorithm while expanding a stack structure for the obtained signal vector.

### JOINT RESEARCH AGREEMENT

The claimed invention was made by, on behalf of, and/or in connection with one or more of the following parties to a joint research agreement: Research and Industrial Cooperation Group and Samsung Electronics Co., Ltd. The agreement was in effect on and before the date the claimed invention was made, and the claimed invention was made as a result of activities undertaken within the scope of the agreement.

### PRIORITY

This application claims the benefit under 35 U.S.C. § 119(a) of a Korean patent application filed on Jun. 15, 2007 in the Korean Intellectual Property Office and assigned Serial No. 2006-53867, the entire disclosure of which is hereby incorporated by reference.

### BACKGROUND OF THE INVENTION

1. Field of the Invention

The present invention relates to a Multi-Input Multi-Output (MIMO) system. More particularly, the present invention relates to an apparatus and method for detecting a signal in a MIMO system.

2. Description of the Related Art

In general, a mobile communication system employs decoding schemes such as a Viterbi decoding scheme, a sequential decoding scheme, and a majority decoding scheme. Among these schemes, the Viterbi decoding scheme is popular. Due to its excellent performance, the Viterbi decoding scheme is used in a Code Division Multiple Access (CDMA) system. However, since a computation amount and a computation complexity exponentially increase in the Viterbi decoding scheme, it has been difficult to use the Viterbi decoding scheme when a constraint length is 10 or more.

The sequential decoding scheme has a linearly increasing computation amount. Thus, the sequential decoding scheme can be used to achieve a high-functional decoder having a constraint length of 30. Further, the sequential decoding scheme can be performed at a speed faster than the Viterbi decoding scheme. Some examples of the sequential decoding scheme include a Fano algorithm and a stack algorithm, each of which computes branch metrics to obtain an optimal path.

According to the stack algorithm, branch metrics are computed for all available forward nodes to obtain an optimal path. Branch metrics are then computed again for all available forward nodes along the optimal path, and the computed branch metrics are reallocated in the stack. Thus, when using the stack algorithm, a computation amount can be reduced. However, there is a demerit in that more memory space is required. For example, in a stack structure viewed from a k^{th} tree level, a required memory space is equal to a modulation order (e.g., M in the case of M-Quadrature Amplitude Modulation (QAM)). In a stack structure viewed from a (k+1)^{th} tree level, a required memory space is equal to (2M−1). In this case, a memory overflow occurs. In order to avoid the memory overflow, a scheme has been proposed in which memory reallocation is achieved so that a memory space is maintained to M. However, in this scheme, performance is inferior to a Maximum Likelihood (ML) scheme. Although performance can be improved by reducing the memory space, this is not a proper solution because errors may frequently occur during a decoding process when the memory space is reduced.

Meanwhile, the mobile communication system employs an Orthogonal Frequency Division Multiplexing (OFDM) scheme in which signals are transmitted through a plurality of sub-channels. Therefore, in a system based on the OFDM scheme, an array antenna may be used for a plurality of users (i.e., Mobile Stations (MSs)). The system may be a Space Division Multiplexing Access (SDMA) system which uses a smart antenna concept on the basis of the OFDM scheme.

Several signal detection schemes related to the OFDM/SDMA system have been proposed. The signal detection schemes may be either a linear scheme or a non-linear scheme. Examples of the linear scheme include a Zero Forcing (ZF) scheme and a Minimum Mean Squares Error (MMSE) scheme. Examples of the non-linear scheme include a MMSE-Ordered Successive Interference Cancellation (OSIC) scheme, a Successive Interference Cancellation (SIC) scheme, a Parallel Interference Cancellation (PIC) scheme, and a Maximum Likelihood (ML) scheme.

Each signal detection scheme has a different performance and a different computation complexity. In particular, the ZF scheme and the MMSE scheme, each of which is included in the linear scheme, have a limit in supporting a plurality of users. This is because performance deterioration becomes significant as the number of users increases. The ML scheme is known as the optimal scheme among the several non-linear schemes. However, in spite of its excellent performance, the ML scheme has a problem in requiring a high computation complexity. Accordingly, there is a demand for a signal detection method having a low computation complexity and a high performance.

### SUMMARY OF THE INVENTION

An aspect of the present invention is to address at least the above-mentioned problems and/or disadvantages and to provide at least the advantages described below. Accordingly, an aspect of the present invention is to provide an apparatus and method for detecting a signal using a modified stack algorithm in a Multi-Input Multi-Output (MIMO) system.

Another aspect of the present invention is to provide an apparatus and method for detecting a signal with a low computation complexity and a high performance using a modified stack algorithm in a MIMO system

According to one aspect of the present invention, a signal detection method of a MIMO system is provided. The method includes sorting signals received via antennas and channel coefficients for respective users in descending order, decomposing a channel matrix composed of the sorted channel coefficients into a unitary matrix and an upper-triangular matrix, determining the number of candidate symbol-sequences using the decomposed upper-triangular matrix, obtaining a signal vector for the antennas by using the sorted signals received via respective antennas and the unitary matrix, wherein the signal vector is proportional to the upper-triangular matrix, and detecting the determined number of candidate symbol-sequences by using a modified stack algorithm while expanding a stack structure for the obtained signal vector.

According to another aspect of the present invention, a signal detection apparatus of a MIMO system is provided. The apparatus includes a sorting unit for sorting signals received via antennas and channel coefficients for respective users in descending order, a decomposition unit for decomposing a channel matrix composed of the sorted channel coefficients into a unitary matrix and an upper-triangular matrix and for obtaining a signal vector for the antennas by using the sorted signals received via respective antennas and the unitary matrix, wherein the signal vector is proportional to the upper-triangular matrix, a determining unit for determining the number of candidate symbol-sequences using the decomposed upper-triangular matrix, and a candidate symbol-sequence selector for detecting the determined number of candidate symbol-sequences by using a modified stack algorithm while expanding a stack structure for the obtained signal vector.

According to still another aspect of the present invention, a method for stacking is provided. The method includes loading a stack into a memory together with a first node, computing branch metrics of nodes linked to the first node and allocating the computed branch metrics in the stack, computing branch metrics of nodes linked to a node whose branch metric is stored in the top of the stack, and deleting the top stack entry from the stack and reallocating the stack so that the computed branch metrics are included in the stack.

### BRIEF DESCRIPTION OF THE DRAWINGS

The above and other objects, features and advantages of certain exemplary embodiments of the present invention will become more apparent from the following detailed description when taken in conjunction with the accompanying drawings in which:

FIG. 1 is a block diagram illustrating a transmitter/receiver of a Multi-Input Multi-Output (MIMO) system according to an exemplary embodiment of the present invention;

FIG. 2 is a block diagram illustrating a detector included in a receiver of a MIMO system according to an exemplary embodiment of the present invention;

FIG. 3 is a flowchart illustrating a signal detection method using a modified stack algorithm in a MIMO system according to an exemplary embodiment of the present invention;

FIGS. 4A to 4D are views for illustrating an effective process of forming a stack structure in a MIMO system according to an exemplary embodiment of the present invention;

FIGS. 5A to 5C and 6A and 6D are views for illustrating a signal detection method using a modified stack algorithm in a MIMO system according to an exemplary embodiment of the present invention;

FIG. 7 is a graph for comparing a Bit Error Ratio (BER) of a modified stack algorithm of an exemplary embodiment of the present invention with respect to other conventional non-linear algorithms; and

FIG. 8 is a graph for comparing a computation complexity of a modified stack algorithm of an exemplary embodiment of the present invention with respect to other conventional non-linear algorithms.

Throughout the drawings, like reference numerals will be understood to refer to like parts, components and structures.

### DETAILED DESCRIPTION OF EXEMPLARY EMBODIMENTS

The following description with reference to the accompanying drawings is provided to assist in a comprehensive understanding of the exemplary embodiments of the present invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness. Terminology used herein should be determined in consideration of functionality of the present invention, and it may be variable depending on users' or operator's intention, or customs in the art. Therefore, corresponding meaning should be determined with reference to the entire specification.

Hereinafter, the present invention of a signal detection apparatus and method using a modified stack algorithm in a Multi-Input Multi-Output (MIMO) system will be described. The present invention may also apply to various other apparatuses and methods used in the MIMO system.

In the modified stack algorithm, a signal is detected using a tree search scheme. A tree level is determined according to the number of antennas included in the MIMO system.

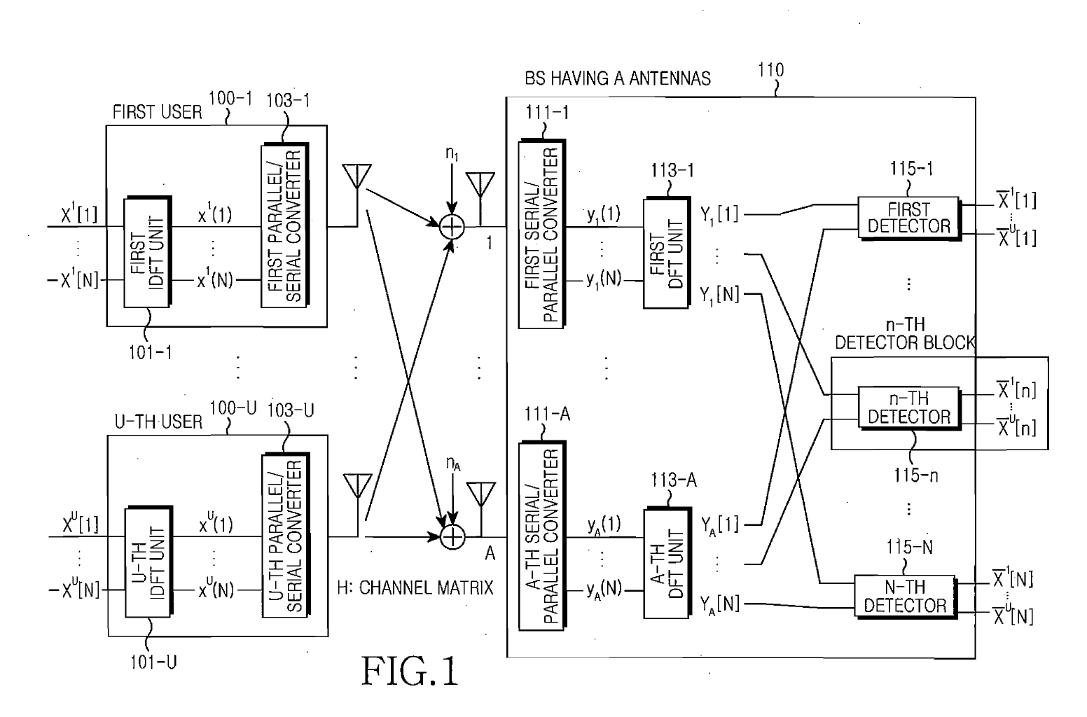

FIG. 1 is a block diagram illustrating a transmitter/receiver of a MIMO system according to an exemplary embodiment of the present invention.

Referring to FIG. 1, a total of U users (i.e., Mobile Stations (MSs)) 100-1 to 100-U, each having one antenna, transmit signals to a Base Station (BS) 110. Prior to transmission, the signals are subject to an Inverse Discrete Fourier Transform (IDFT) operation and a parallel/serial conversion operation. The users 100-1 to 100-U respectively include IDFT units 101-1 to 101-U and parallel/serial converters 103-1 to 103-U. The IDFT units 101-1 to 101-U perform an IDFT operation on a total of N signals respectively transmitted from the users 100-1 to 100-U and then output the signals to the parallel/serial converters 103-1 to 103-U. The parallel/serial converters 103-1 to 103-U convert the signals which have undergone the IDFT operation into serial signals and then transmit the converted signals to the BS 110.

The BS 110 has a total of A antennas. The signals transmitted from the users 100-1 to 100-U are received via the A antennas. Then, for each antenna, the received signals are subject to a serial/parallel conversion operation and a Discrete Fourier Transform (DFT) operation, and are output to detectors 115-1 to 115-N. The BS 110 includes serial/parallel converters 111-1 to 111-A and DFT units 113-1 to 113-A for the A antennas. Further, the BS 110 includes the detectors 115-1 to 115-N for the N signals. The serial/parallel converters 111-1 to 111-A convert the signals transmitted via the antennas into parallel signals and then output the converted parallel signals to the DFT units 113-1 to 113-A. The DFT units 113-1 to 113-A perform a DFT operation on the converted signals and then output the signals to the detectors 115-1 to 115-N. The detectors 115-1 to 115-N restore the signals transmitted from the DFT units 113-1 to 113-A.

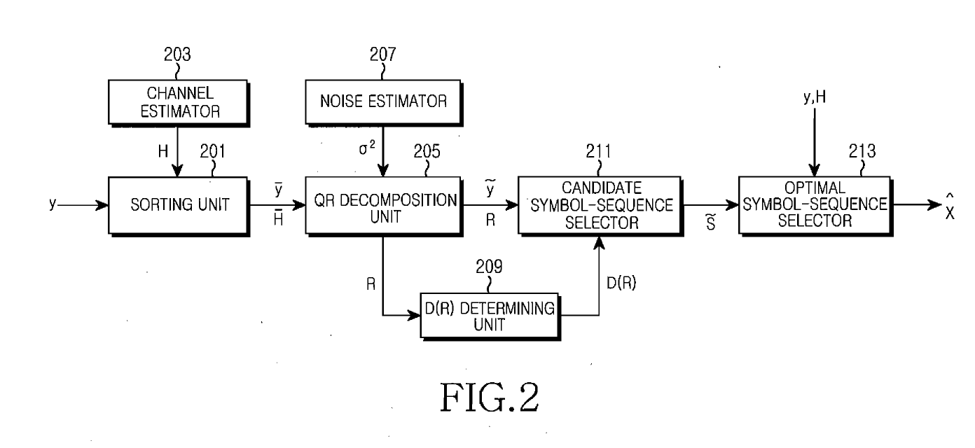

FIG. 2 is a block diagram illustrating a detector included in a receiver of a MIMO system according to an exemplary embodiment of the present invention. The detector includes a sorting unit 201, a channel estimator 203, a QR decomposition unit 205, a noise estimator 207, a D(R) determining unit 209, a candidate symbol-sequence selector 211, and an optimal symbol-sequence selector 213.

Referring to FIG. 2, the channel estimator 203 estimates a channel coefficient between each user and a BS by using a preamble of a received signal. Then, the channel estimator 203 outputs a channel matrix H composed of channel coefficients for respective users to the sorting unit 201.

The sorting unit 201 sorts signals y in descending order, wherein the signals y are received from a plurality of users via multiple antennas. Further, the sorting unit 201 also sorts channel coefficients constituting the channel matrix H estimated by the channel estimator 203, in descending order. Then, the sorting unit 201 outputs sorted signals y̅ and a channel matrix H̅ composed of the sorted channel coefficients to the QR decomposition unit 205.

The noise estimator 207 estimates a noise of a received signal and outputs a variation σ² of the estimated noise to the QR decomposition unit 205.

By using a noise variation σ² input from the noise estimator 207, the QR decomposition unit 205 decomposes the sorted channel matrix H̅ input from the sorting unit 201 into a Q factor (i.e., unitary matrix) and an R factor (i.e., upper-triangular matrix). Then, the QR decomposition unit 205 outputs the R factor to the D(R) determining unit 209 and the candidate symbol-sequence selector 211. In addition, the QR decomposition unit 205 outputs signals \tilde{y} to the candidate symbol-sequence selector 211, wherein the signals \tilde{y} are estimated by using the sorted signals y̅ and the Q and R factors.

The D(R) determining unit 209 determines the number of symbol sequences according to a channel state by using the R factor input from the QR decomposition unit 205. Then, the D(R) determining unit 209 outputs the determined number of the symbol sequences to the candidate symbol-sequence selector 211.

The candidate symbol-sequence selector 211 computes a branch metric for each tree level by using the R factor and the estimated signals \tilde{y} input from the QR decomposition unit 205. Then, by using the computed branch metric and the number of symbol sequences input from the D(R) determining unit 209, the candidate symbol-sequence selector 211 selects a candidate symbol-sequence according to a tree searching result. In this case, a plurality of candidate symbol-sequences may be selected. In other words, if a channel state is good, a symbol to be transmitted can be selected using only one node, and otherwise, a plurality of candidate symbol-sequences may be selected, and the optimal symbol-sequence selector 213 may select one of the candidate symbol-sequences. A set \tilde{S} of selected candidate symbol-sequences is then output to the optimal symbol-sequence selector 213.

By using the set \tilde{S} of the selected candidate symbol-sequences (i.e., candidate set) input from the candidate symbol-sequence selector 211, the optimal symbol-sequence selector 213 computes a Joint Maximum Likelihood (JML) metric J(s) only for a signal vector s in association with the candidate set \tilde{S} by using the signals y and the channel matrix H. Then, the optimal symbol-sequence selector 213 determines a symbol sequence having a minimum JML metric as an optimal symbol sequence \hat{X}.

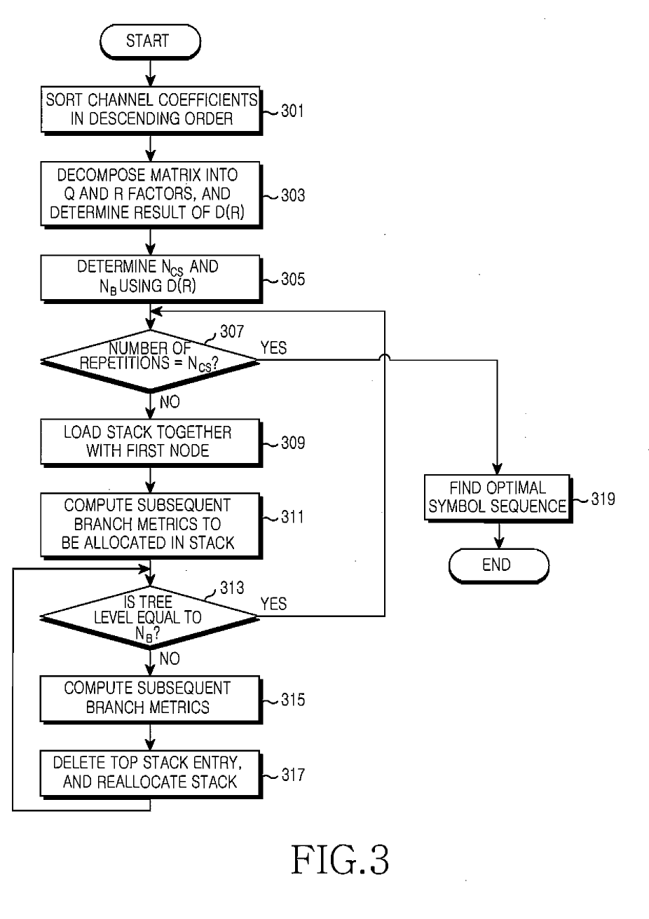

FIG. 3 is a flowchart illustrating a signal detection method using a modified stack algorithm in a MIMO system according to an exemplary embodiment of the present invention.

Referring to FIG. 3, in step 301, channel coefficients for respective users are sorted in descending order, and signals y are also sorted in descending order.

For example, in a system using a Binary Phase Shift Keying (BPSK) scheme, if the number of users having one antenna is 4, and a BS having four antennas exists, then the signals y transmitted from the users to the BS may be expressed by Equation (1).

$$y = H x + w \\ \begin{matrix}[ \begin{matrix}{y}_{1} \\ {y}_{2} \\ {y}_{3} \\ {y}_{4}\end{matrix} ] = [ \begin{matrix}{h}_{11} & {h}_{12} & {h}_{13} & {h}_{14} \\ {h}_{21} & {h}_{22} & {h}_{23} & {h}_{24} \\ {h}_{31} & {h}_{32} & {h}_{33} & {h}_{34} \\ {h}_{41} & {h}_{42} & {h}_{43} & {h}_{44}\end{matrix} ] [ \begin{matrix}{x}_{1} \\ {x}_{2} \\ {x}_{3} \\ {x}_{4}\end{matrix} ] + [ \begin{matrix}{w}_{1} \\ {w}_{2} \\ {w}_{3} \\ {w}_{4}\end{matrix} ] \\ = [ \begin{matrix}{h}_{1} & {h}_{2} & {h}_{3} & {h}_{4}\end{matrix} ] [ \begin{matrix}{x}_{1} \\ {x}_{2} \\ {x}_{3} \\ {x}_{4}\end{matrix} ] + [ \begin{matrix}{w}_{1} \\ {w}_{2} \\ {w}_{3} \\ {w}_{4}\end{matrix} ]\end{matrix} \qquad ( 1 )$$

Here, y denotes signals received by a BS, yj is a signal received by a j^{th} receive antenna, x denotes signals transmitted from users, and xᵢ denotes a signal transmitted from an i^{th} user. Each user modulates a signal by using the BPSK modulation scheme, so that xᵢ becomes −1 or 1. In addition, H denotes a channel matrix, hⱼᵢ denotes a channel coefficient between a transmit antenna of an i^{th} user and a j^{th} receive antenna of a BS, and hᵢ denotes a row vector composed of channel coefficients between an i^{th} user and four receive antennas of the BS. Further, w denotes noise, and wⱼ denotes noise of a j^{th} receive antenna of the BS.

When the magnitude of channel coefficient of each user is related as |h3|2>|h2|2>|h1|2>|h4|2, after being sorted in descending order, H and y can be expressed by Equation (2).

$$\overline{H} = [ \begin{matrix}{h}_{3} & {h}_{2} & {h}_{1} & {h}_{4}\end{matrix} ] \\ [ \begin{matrix}{y}_{3} \\ {y}_{2} \\ {y}_{1} \\ {y}_{4}\end{matrix} ] = [ \begin{matrix}{h}_{3} & {h}_{2} & {h}_{1} & {h}_{4}\end{matrix} ] [ \begin{matrix}{x}_{3} \\ {x}_{2} \\ {x}_{1} \\ {x}_{4}\end{matrix} ] + [ \begin{matrix}{w}_{3} \\ {w}_{2} \\ {w}_{1} \\ {w}_{4}\end{matrix} ] \\ \overline{y} = \overline{H} \overline{x} + \overline{w} \\ \overline{y} = [ \begin{matrix}{\overline{y}}_{1} \\ {\overline{y}}_{2} \\ {\overline{y}}_{3} \\ {\overline{y}}_{4}\end{matrix} ] = [ \begin{matrix}{y}_{3} \\ {y}_{2} \\ {y}_{1} \\ {y}_{4}\end{matrix} ] , \\ \overline{x} = [ \begin{matrix}{\overline{x}}_{1} \\ {\overline{x}}_{2} \\ {\overline{x}}_{3} \\ {\overline{x}}_{4}\end{matrix} ] = [ \begin{matrix}{x}_{3} \\ {x}_{2} \\ {x}_{1} \\ {x}_{4}\end{matrix} ] , \\ \overline{w} = [ \begin{matrix}{\overline{w}}_{1} \\ {\overline{w}}_{2} \\ {\overline{w}}_{3} \\ {\overline{w}}_{4}\end{matrix} ] = [ \begin{matrix}{w}_{3} \\ {w}_{2} \\ {w}_{1} \\ {w}_{4}\end{matrix} ] \qquad ( 2 )$$

In step 303, the channel matrix H̅ sorted according to Equation (2) is decomposed into a Q factor and an R factor by using a QR decomposition scheme. Further, a result of the function D(R) is obtained by using the decomposed R factor. D(R) is a determination function for determining the number N_{CS} of candidate symbol-sequences according to the channel state. The QR decomposition may be performed on the basis of a Minimum Mean Squares Error (MMSE) scheme. In step 305, the number N_{CS} of the candidate symbol-sequences is determined by using the determined D(R), and the number N_{B} of branches is determined by using the number of antennas. By the use of the determined number of candidate sequence numbers, error propagation can decrease.

The channel decomposition using the QR decomposition scheme can be expressed by Equation (3).

$$\begin{matrix}\overline{H} = [ \begin{matrix}H \\ {σ}_{n} {I}_{U}\end{matrix} ] \\ = QR \\ = [ \begin{matrix}{q}_{11} & {q}_{12} & {q}_{13} & {q}_{14} \\ {q}_{21} & {q}_{22} & {q}_{23} & {q}_{24} \\ {q}_{31} & {q}_{32} & {q}_{33} & {q}_{34} \\ {q}_{41} & {q}_{42} & {q}_{43} & {q}_{44}\end{matrix} ] [ \begin{matrix}{r}_{11} & {r}_{12} & {r}_{13} & {r}_{14} \\ 0 & {r}_{22} & {r}_{23} & {r}_{24} \\ 0 & 0 & {r}_{33} & {r}_{34} \\ 0 & 0 & 0 & {r}_{44}\end{matrix} ]\end{matrix} \qquad ( 3 )$$

Here, H̅ denotes a channel matrix in which a channel matrix H is sorted according to the magnitude of channel coefficient for each user, and Q denotes a unitary matrix. I is a unitary matrix which can be expressed by QHQ, where (•)H denotes a transpose conjugate, R denotes an upper-triangular matrix, and σₙ denotes a noise variation.

The determination function D(R) can be expressed by Equation (4).

$$D ( R ) = ( \begin{matrix}a , & all ( diag ( R ) \geq γ ) \\ b , & otherwise\end{matrix} ) \qquad ( 4 )$$

Here, all(diag(•)) denotes all diagonal elements of a corresponding matrix. a and b are values ranging from 1 to a modulation order (e.g., 16 in the case of 16 QAM), and γ is a real number greater than 0. For example, if the diagonal elements of the upper-triangular matrix is equal to or greater than γ, the channel state is good, and the D(R) is determined to a (e.g., 1). If some of the diagonal elements of the upper triangular matrix R are less than γ, the channel state is poor, and the D(R) is determined to b (e.g., modulation order). This means that, when the channel state is good, it is possible to find out an optimal symbol sequence even if the number N_{CS} of the candidate symbol-sequences is determined to a smaller number, and when the channel state is poor, the optimal symbol sequence can be found only when the number N_{CS} of the candidate symbol-sequences is determined to be a larger number.

After such initialization process is performed, the N_{CS} symbol sequences are searched for. While searching for the symbol sequences, a stack structure is expanded using the determined number N_{B} of branches. Further, a branch metric is computed by using a Euclidian distance. The symbol sequences composed of symbols and having difference lengths are compared by using the branch metric.

A distance between the signals y and a product H·s of a channel matrix H and a signal vector s can be expressed by Equation (5). Accordingly, an errorless signal can be obtained only when a signal having a minimum Euclidian distance is detected.

E{∥y−Hs∥²}=Uσₙ² (5)

By using the sorted signals y̅ and the Q factor, estimated signals \tilde{y} proportional to the R factor can be obtained according to Equation (6).

$$\tilde{y} = {Q}^{H} \overline{y} = {Q}^{H} ( QR \overline{x} + \overline{w} ) = R \overline{x} + {Q}^{H} \overline{w} = R \overline{x} + \tilde{w} \\ [ \begin{matrix}{\tilde{y}}_{1} \\ {\tilde{y}}_{2} \\ {\tilde{y}}_{3} \\ {\tilde{y}}_{4}\end{matrix} ] = [ \begin{matrix}{r}_{11} & {r}_{12} & {r}_{13} & {r}_{14} \\ 0 & {r}_{22} & {r}_{23} & {r}_{24} \\ 0 & 0 & {r}_{33} & {r}_{34} \\ 0 & 0 & 0 & {r}_{44}\end{matrix} ] [ \begin{matrix}{\overline{x}}_{1} \\ {\overline{x}}_{2} \\ {\overline{x}}_{3} \\ {\overline{x}}_{4}\end{matrix} ] + [ \begin{matrix}{\tilde{w}}_{1} \\ {\tilde{w}}_{2} \\ {\tilde{w}}_{3} \\ {\tilde{w}}_{4}\end{matrix} ] \\ {\tilde{y}}_{k} = {r}_{k , k} {\overline{x}}_{k} + {\sum }_{i = k + 1}^{U} {r}_{k , i} {\overline{x}}_{i} + {\tilde{w}}_{k} \qquad ( 6 )$$

Here, \tilde{y}ₖ denotes a k^{th} estimated signal, r_{k,k} denotes a (k, k) element of an upper-triangular matrix, and \tilde{w}ₖ denotes a k^{th} noise component. The BS may detect all elements of x̅ₖ in the order of from x̅₄ to x̅₁. For example, x̅₄ is first detected, components of x̅₄ are removed so as to detect x̅₃, and the remaining elements of x̅ₖ are detected in the same manner.

In order to compare symbol sequences having different length from one another, a metric bias is defined as Equation (7). The metric bias is an offset value for adjusting the symbol sequences having different lengths from one another to have the same length. The offset value varies depending on a tree level.

Fₖ=Fₖ₋₁+ασₙ²r_{k-1,k-1}², αε[01], k=2, . . . ,U−1 (7)

Therefore, a branch metric using the metric bias can be computed according to Equation (8).

$$\begin{matrix}{BM}_{i , k} = \vert \frac{{\tilde{y}}_{k} - {\sum }_{i = k + 1}^{U} {r}_{k , i} {\overline{x}}_{i}}{{r}_{k , k}} - {c}_{i} \vert {F}_{k} , & ( k = 1 , ⋯ U . i = 1 , ⋯ , M )\end{matrix} \qquad ( 8 )$$

Here, BM_{i,k} denotes a Euclidian distance between a signal x̅ₖ corresponding to a k^{th} tree level and an i^{th} element of a signal constellation. cᵢ denotes one element on a signal constellation.

The process of searching for a candidate symbol-sequence will now be described in detail. In step 307, it is determined whether the number of repetitions of the search process is equal to N_{CS}. If the number of repetitions is not equal to N_{CS}, in step 309, a stack is loaded into a memory together with a first node of a tree structure. In step 311, branch metrics for two forward nodes linked to the first node are computed, and the computed branch metrics are allocated and stored in the stack in ascending order.

In step 313, it is determined whether a tree level of a top stack entry is equal to the number of branches. If this tree level is not equal to the number of branches, in step 315, branch metrics of nodes linked to a node whose branch metric is stored in the top of the stack are computed. In step 317, the top stack entry is deleted from the stack, and the stack is reallocated by using the remaining branch metrics stored in the stack and the computed branch metrics. The procedure is then returned back to step 313.

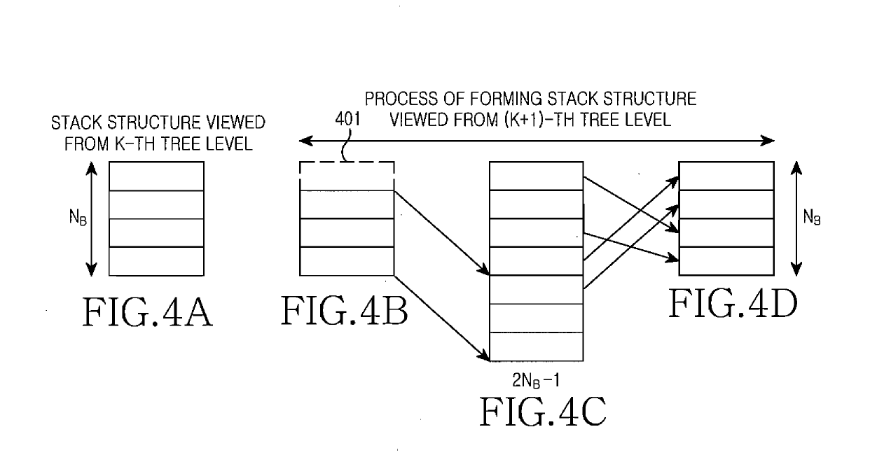

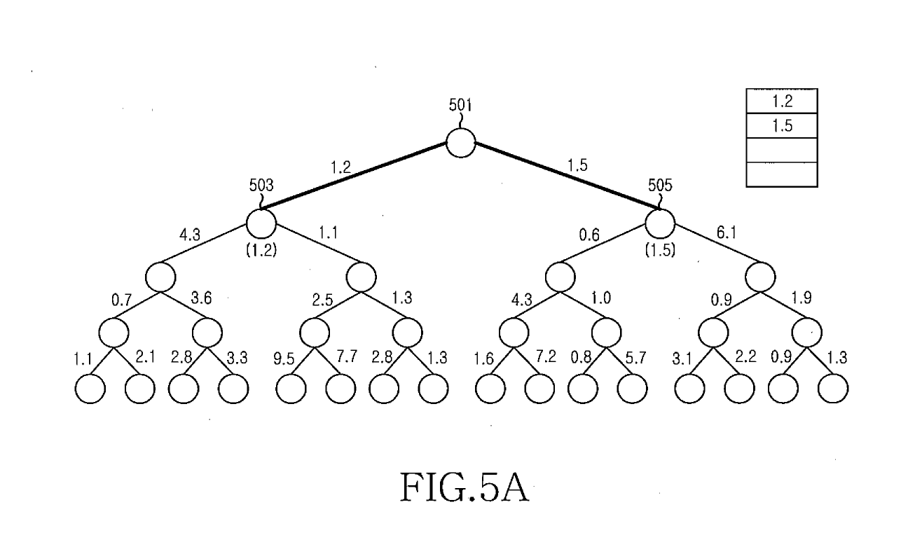

Meanwhile, an effective stack structure is formed as shown in FIGS. 4A to 4D. A stack viewed from a k^{th} tree level is depicted in FIG. 4A. A top stack entry 401 is deleted from this stack (see FIG. 4B). A depth of the stack structure, that is, a memory size, can be determined according to the number N_{B} of branches. In a state that the top stack entry 401 is deleted (see FIG. 4B), when the stack structure is expanded (see FIG. 4C), the expanded stack structure has a depth of 2N_{B}−1. The expanded stack structure is reallocated to form a stack structure (see FIG. 4D) which is viewed from a (K+1)^{th} tree level. In other words, the memory size is expanded up to 2N_{B}−1, and after reallocation, the memory size maintains to N_{B}.

If the tree level of the top stack entry is equal to the number of branches in step 313, it is determined that one candidate symbol-sequence has been found through steps 309 to 317. Then, returning back to step 307, the process of searching for candidate symbol-sequences is repeated by the aforementioned number of repetitions. The reason for repeating the process is to find out an optimal symbol sequence while selecting only one symbol sequence from among a plurality of symbol sequences. In other words, when a channel state is good, a transmitted symbol is determined by selecting only one candidate symbol-sequence. When the channel state is bad, one symbol is selected from the plurality of candidate symbols in step 319.

If the number of repetitions is equal to N_{CS} in step 307, it is determined that the candidate symbol-sequences have been searched for by the number of repetitions. In step 319, one symbol is selected from the found candidate symbol-sequences, thereby obtaining an optical symbol sequence. The optimal symbol sequence has a minimum JML metric among the candidate symbol-sequences.

The JML metric can be expressed by Equation (9).

$$\begin{matrix}J ( s ) = {‖ y - Hs ‖}^{2} \\ = [ Re \{ {y}^{H} y \} - 2 Re \{ {s}^{H} {H}^{H} y \} + Re \{ {s}^{H} {H}^{H} Hs \} ]\end{matrix} \qquad ( 9 )$$

Here, s denotes a candidate symbol-sequence. The minimum JML metric can be expressed by Equation (10).

$$x = \begin{matrix}arg min \\ s ∈ \tilde{S}\end{matrix} J ( s ) , N ( \tilde{S} ) = D ( R ) \qquad ( 10 )$$

Here, \tilde{S} denotes a set of candidate symbol-sequences. J(s) is computed only for the candidate symbol-sequences s included in the set \tilde{S}. The optimal symbol sequence is a symbol sequence having a minimum Euclidian distance.

The procedure is then ended.

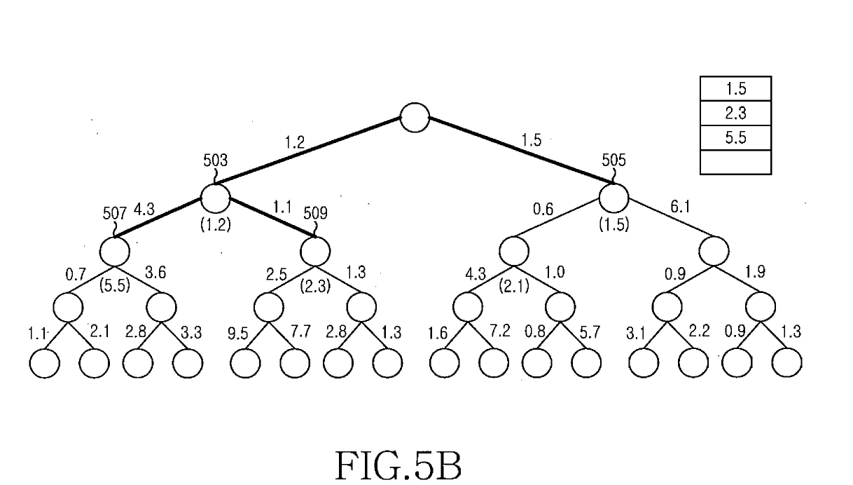

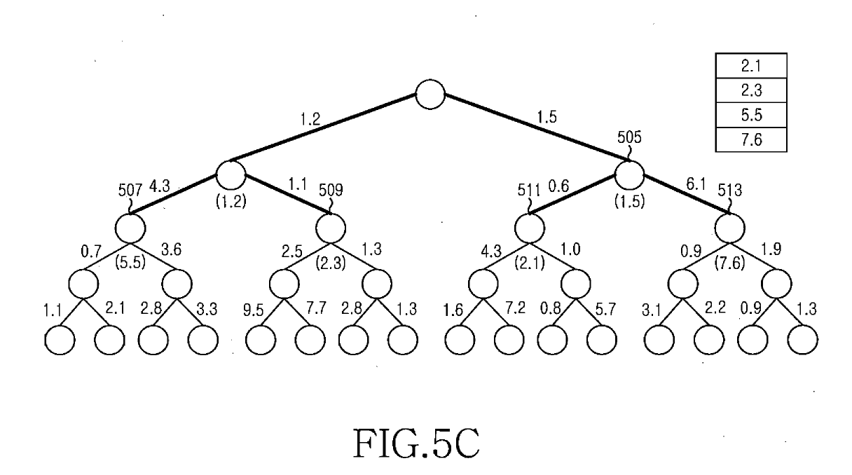

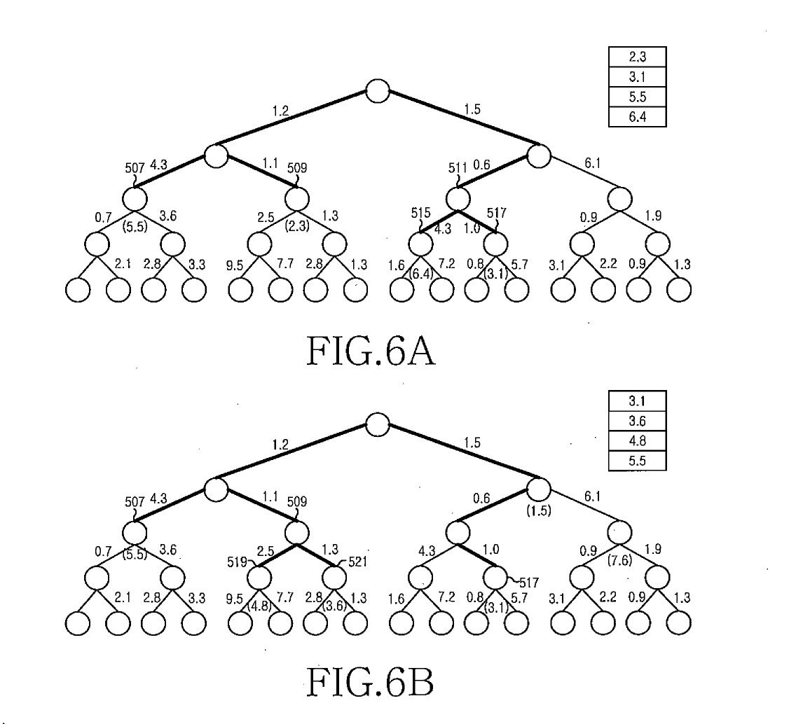

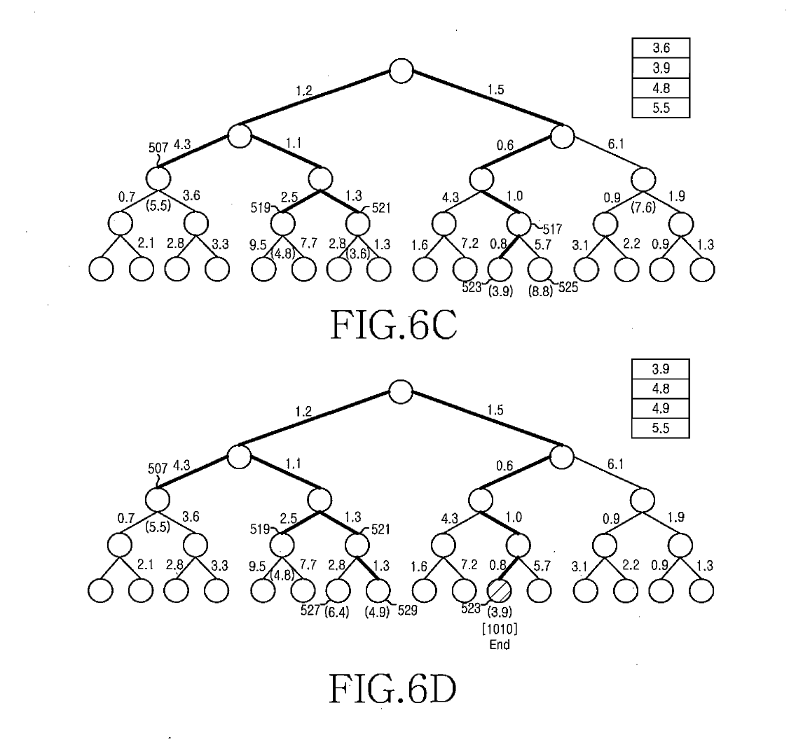

FIGS. 5A to 5C and 6A to 6D are views for illustrating a signal detection method using a modified stack algorithm in a MIMO system according to an exemplary embodiment of the present invention. For example, when four users transmit four data streams by using a BPSK scheme, a total number of signals that can be transmitted by the users is 2⁴ (=16). According to an exemplary embodiment of the present invention, metrics are computed for a node whose metric is stored in the top of the stack, and then computation proceeds to a subsequent lower tree level. When the computed metrics are re-stored in the stack, the metrics are reallocated in ascending order. When a metric of a node corresponding to the bottom level of the tree structure is stored in the top of the stack, it is determined that the node is in association with a candidate symbol-sequence. As a result, an exemplary embodiment of the present invention can reduce a computation complexity as compared with a conventional method in which all metrics are computed for 16 nodes located at the bottom level of the tree structure.

Since each user modulates a signal by using the BPSK modulation scheme, a signal xᵢ of an i^{th} user becomes −1 or 1. Branch metrics of nodes linked to a first node 501 of the tree structure are obtained when x₄ is −1 or 1 in Equation (6). Branch metrics of nodes linked to second nodes 503 and 505 are obtained when x₃ is −1 or 1 in Equation (6). Likewise, branch metrics are computed for the rest of nodes. [x₄ x₃ x₂ x₁] denotes the bottom nodes of the tree structure. For example, the leftmost bottom level nodes of the tree structure may be [−1−1−1−1].

Referring to FIGS. 5A to 5C and 6A to 6D, branch metrics for two forwards nodes 503 and 505 linked to the first node 501 are computed. As a result, branch metrics of 1.2 and 1.5 are respectively obtained for the two forwards nodes 503 and 505. The computed branch metrics are allocated and stored in the stack in the ascending order (see FIG. 5A).

Branch metrics are then computed for two forward nodes 507 and 509 linked to the node 503 corresponding to the smallest metric among the branch metrics stored in the stack, that is, a branch metric allocated in the top of the stack. In this case, the computed branch metrics for the two forward nodes 507 and 509 are respectively 5.5 and 2.3. A branch metric 1.2 for the node 503 is deleted from the stack, and branch metrics 1.5, 2.3, and 5.5 for the nodes 505, 509, and 507, respectively, are allocated and stored in the stack in that order (see FIG. 5B).

Branch metrics are then computed for two forward nodes 511 and 513 linked to the node 505 corresponding to the smallest metric among the branch metrics stored in the stack, that is, a branch metric allocated in the top of the stack. In this case, the computed branch metrics for the two forward nodes 511 and 513 are respectively 2.1 and 7.6. A branch metric 1.5 for the node 505 is deleted from the stack, and branch metrics 2.1, 2.3, 5.5 and 7.6 for the nodes 511, 509, 507, and 513, respectively, are allocated and stored in the stack in that order (see FIG. 5C).

Branch metrics are then computed for two forward nodes 515 and 517 linked to the node 511 corresponding to the smallest metric among the branch metrics stored in the stack, that is, a branch metric allocated in the top of the stack. In this case, the computed branch metrics for the two forward nodes 515 and 517 are respectively 6.4 and 3.1. A branch metric 2.1 for the node 511 is deleted from the stack, and branch metrics 2.3, 3.1, 5.5, and 6.4 for the nodes 509, 517, 507, and 515, respectively, are allocated and stored in the stack in that order (see FIG. 6A).

Branch metrics are then computed for two forward nodes 519 and 521 linked to the node 509 corresponding to the smallest metric among the branch metrics stored in the stack, that is, a branch metric allocated in the top of the stack. In this case, the computed branch metrics for the two forward nodes 519 and 521 are respectively 4.8 and 3.6. A branch metric 2.3 for the node 509 is deleted from the stack, and branch metrics 3.1, 3.6, 4.8, and 5.5 for the nodes 517, 521, 519, and 507, respectively, are allocated and stored in the stack in that order (see FIG. 6B).

Branch metrics are then computed for two forward nodes 523 and 525 linked to the node 517 corresponding to the smallest metric among the branch metrics stored in the stack, that is, a branch metric allocated in the top of the stack. In this case, the computed branch metrics for the two forward nodes 523 and 525 are respectively 3.9 and 8.8. A branch metric 3.1 for the node 517 is deleted from the stack, and branch metrics 3.6, 3.9, 4.8, and 5.5 for the nodes 521, 523, 519, and 507, respectively, are allocated and stored in the stack in that order (see FIG. 6C).

Branch metrics are then computed for two forward nodes 527 and 529 linked to the node 521 corresponding to the smallest metric among the branch metrics stored in the stack, that is, a branch metric allocated in the top of the stack. In this case, the computed branch metrics for the two forward nodes 527 and 529 are respectively 6.4 and 4.9. A branch metric 3.6 for the node 521 is deleted from the stack, and branch metrics 3.9, 4.9, 4.8, and 5.5 for the nodes 523, 529, 519, and 507, respectively, are allocated and stored in the stack in that order (see FIG. 6D). The tree level of the top stack entry is equal to the number of branches, and thus the stack algorithm is ended.

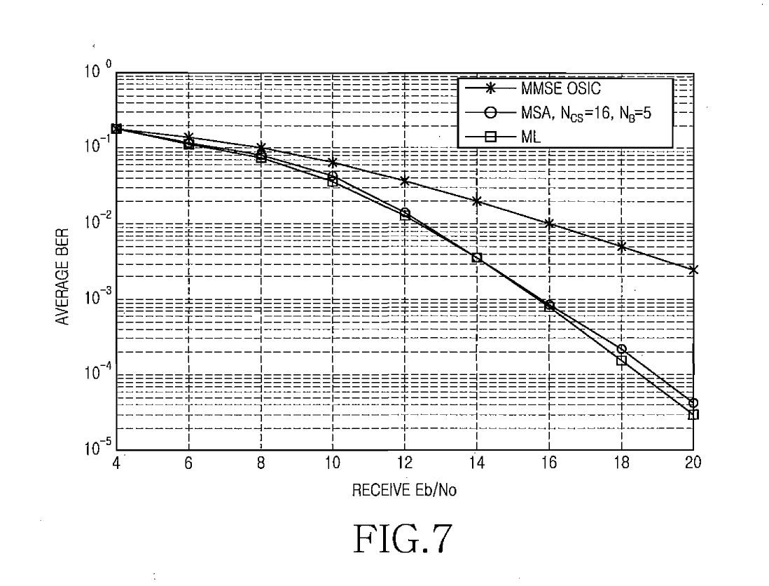

FIG. 7 is a graph for comparing a Bit Error Ratio (BER) of a modified stack algorithm of an exemplary embodiment of the present invention with respect to other conventional non-linear algorithms. Herein, the number of users is 4, a BS has four receive antennas, and a system uses 16 QAM. Referring to FIG. 7, the modified stack algorithm of an exemplary embodiment of the present invention shows the similar performance as the ML scheme known for the optimal non-linear scheme.

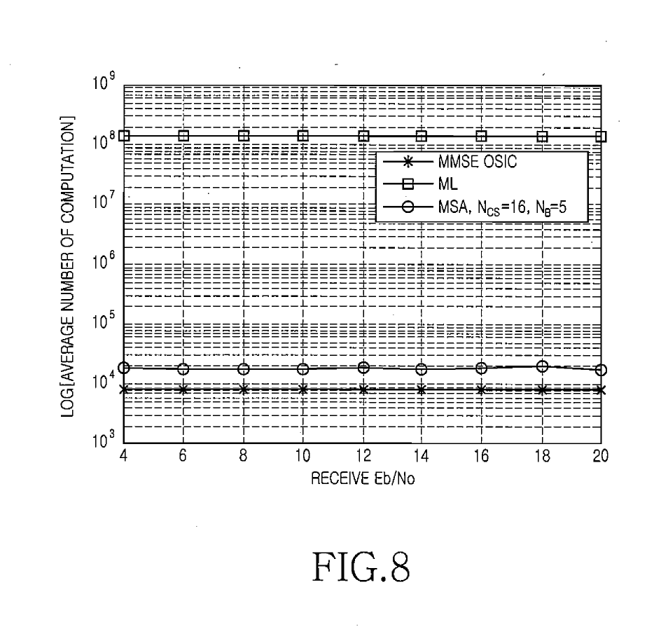

FIG. 8 is a graph for comparing a computation complexity of a modified stack algorithm of an exemplary embodiment of the present invention with respect to other conventional non-linear algorithms. Herein, the number of users is 4, a BS has four receive antennas, and a system uses 16 QAM. Referring to FIG. 8, the modified stack algorithm of an exemplary embodiment of the present invention can effectively reduce a computation complexity which is restricted in the ML scheme known for the optimal non-linear scheme.

According to certain exemplary embodiments of the present invention of a signal detection apparatus and method having a low computation complexity and a high performance and using a modified stack algorithm in a MIMO system, a memory space can be effectively used by addressing a problem of a memory space limit of the conventional stack algorithm. In addition, a computation complexity can be effectively reduced which has been a constraint of the ML scheme known for the optimal non-linear scheme. Moreover, certain exemplary embodiments of the present invention can expect a performance similar to the ML scheme.

While the invention has been shown and described with reference to certain exemplary embodiments thereof, it will be understood by those skilled in the art that various changes in form and details may be made therein without departing from the spirit and scope of the invention as defined by the appended claims and their equivalents. Therefore, the scope of the invention is defined not by the detailed description of the invention but by the appended claims, and all differences within the scope will be construed as being included in the present invention.

What is claimed is:

1. A signal detection method of a Multi-Input Multi-Output (MIMO) system, comprising:
sorting signals received via antennas and channel coefficients for respective users in descending order;
decomposing a channel matrix composed of the sorted channel coefficients into a unitary matrix and an upper-triangular matrix;
determining the number of candidate symbol-sequences using the upper-triangular matrix;
obtaining a signal vector for the antennas using the sorted signals received via respective antennas and the unitary matrix, the signal vector being proportional to the upper-triangular matrix; and
detecting the determined number of candidate symbol-sequences using a modified stack algorithm while expanding a stack structure for the obtained signal vector.

2. The signal detection method of claim 1, wherein, the detecting of the candidate symbol-sequences comprises:
detecting a signal transmitted via one antenna by using bottom elements of the upper-triangular matrix;
removing components of the detected signal; and
detecting other signals transmitted via the rest of antennas.

3. The signal detection method of claim 1, further comprising:
computing a Joint Maximum Likelihood (JML) metric of the detected candidate symbol-sequences; and
selecting a candidate symbol-sequence having a minimum JML as an optimal symbol sequence.

4. The signal detection method of claim 1, further comprising determining the number of branches according to the number of antennas.

5. The signal detection method of claim 4, further comprising expanding a stack structure according to the determined number of branches.

6. The signal detection method of claim 1, wherein the determined number of candidate symbol-sequences is equal to a value ranging from 1 to a modulation order.

7. The signal detection method of claim 6, wherein, when all diagonal elements of the decomposed upper-triangular matrix are above a reference value, the number of candidate symbol-sequences is approximately 1, where the value ranges from 1 to the modulation order.

8. The signal detection method of claim 1, wherein the modified stack algorithm comprises:
loading a stack into a memory together with a first node;
computing branch metrics of nodes linked to the first node and allocating the computed branch metrics in the stack;
computing branch metrics of nodes linked to a node whose branch metric is stored in the top of the stack; and
deleting a top stack entry from the stack and reallocating the stack so that the computed branch metrics are included in the stack.

9. The signal detection method of claim 8, further comprising allocating the branch metrics in the stack in ascending order.

10. The signal detection method of claim 8, wherein the branch metrics of nodes linked to the node whose branch metric is stored in the top of the stack are repeatedly computed until a tree level of the top stack entry is equal to the number of branches.

11. The signal detection method of claim 8, further comprising computing the branch metrics by using a metric bias so that symbol sequences having different lengths from one anther can have the same length.

12. The signal detection method of claim 8, wherein the metric bias is defined by: Fₖ=Fₖ₋₁+ασₙ²r_{k-1,k-1}², αε[01], k=2, . . . ,U−1 where r denotes an element of an upper-triangular matrix, U denotes the number of users, and σₙ denotes a noise variation.

13. The signal detection method of claim 8, wherein the branch metric is Computed according to:
$${BM}_{i , k} = {\vert \frac{{\tilde{y}}_{k} - {\sum }_{i = k + 1}^{U} {r}_{k , i} {\overline{x}}_{i}}{{r}_{k , k}} - {c}_{i} \vert}^{2} + {F}_{k} , \qquad ( k = 1 , ⋯ U , i = 1 , ⋯ , M ) ,$$
where BM_{i,k} denotes a Euclidian distance between a signal x̅ₖ corresponding to a k^{th} tree level and an i^{th} element of a signal constellation, cᵢ denotes one element on a signal constellation, \tilde{y}ₖ denotes a signal received via each antenna, x̅ₖ denotes a signal sorted according to the magnitude of a channel coefficient for each user in the descending order, r denotes an element of the upper-triangular matrix, U denotes the number of users, M denotes the number of receive antennas, and F denotes a metric bias.

14. A signal detection apparatus of a Multi-Input Multi-Output (MIMO) system, comprising:
a sorting unit for sorting signals received via antennas and channel coefficients for respective users in descending order;
a decomposition unit for decomposing a channel matrix composed of the sorted channel coefficients into a unitary matrix and an upper-triangular matrix and for obtaining a signal vector for the antennas by using the sorted signals received via respective antennas and the unitary matrix, the signal vector being proportional to the upper-triangular matrix;
a determining unit for determining the number of candidate symbol-sequences using the decomposed upper-triangular matrix; and
a candidate symbol-sequence selector for detecting the determined number of candidate symbol-sequences using a modified stack algorithm while expanding a stack structure for the obtained signal vector.

15. The signal detection apparatus of claim 14, wherein the candidate symbol-sequence selector detects a signal transmitted via one antenna using bottom elements of the upper-triangular matrix, removes components of the detected signal, and detects other signals transmitted via the rest of antennas.

16. The signal detection apparatus of claim 14, further comprising an optimal symbol sequence selector for computing a Joint Maximum Likelihood (JML) metric of the detected candidate symbol-sequences and for selecting a candidate symbol-sequence having a minimum JML as an optimal symbol sequence.

17. The signal detection apparatus of claim 14, wherein the candidate symbol-sequence selector expands a stack structure by the number of antennas.

18. The signal detection apparatus of claim 14, wherein the determining unit determines the number of candidate symbol-sequences to a value ranging from 1 to a modulation order.

19. The signal detection apparatus of claim 18, wherein, when all diagonal elements of the decomposed upper-triangular matrix are above a reference value, the determining unit determines the number of candidate symbol-sequences to be approximately 1, where the value ranges from 1 to the modulation order.

20. The signal detection apparatus of claim 14, wherein the candidate symbol-sequence selector comprises:
a means for loading a stack into a memory together with a first node;
a means for computing branch metrics of nodes linked to the first node and for allocating the computed branch metrics in the stack;
a means for computing branch metrics of nodes linked to a node whose branch metric is stored in the top of the stack until a tree level of the top stack entry is equal to the number of branches; and
a means for deleting a top stack entry from the stack and for reallocating the stack so that the computed branch metrics are included in the stack.

21. The signal detection apparatus of claim 20, further comprising means for computing the branch metrics by using a metric bias so that symbol sequences having different lengths from one anther can have the same length.

22. The signal detection apparatus of claim 21, wherein the metric bias is defined by: Fₖ=Fₖ₋₁+ασₙ²r_{k-1,k-1}², αε[01], k=2, . . . ,U−1, where r denotes an element of an upper-triangular matrix, U denotes the number of users, and σₙ denotes a noise variation.

23. The signal detection apparatus of claim 21, wherein the branch metric is computed according to:
$${BM}_{i , k} = {\vert \frac{{\tilde{y}}_{k} - {\sum }_{i = k + 1}^{U} {r}_{k , i} {\overline{x}}_{i}}{{r}_{k , k}} - {c}_{i} \vert}^{2} + {F}_{k} , \qquad ( k = 1 , ⋯ U , i = 1 , ⋯ , M ) ,$$
where BM_{i,k} denotes a Euclidian distance between a signal x̅ₖ corresponding to a k^{th} tree level and an i^{th} element of a signal constellation, cᵢ denotes one element on a signal constellation, \tilde{y}ₖ denotes a signal received via each antenna, x̅ₖ denotes a signal sorted according to the magnitude of a channel coefficient for each user in the descending order, r denotes an element of the upper-triangular matrix, U denotes the number of users, M denotes the number of receive antennas, and F denotes a metric bias.

24. A stack algorithm method comprising:
loading a stack into a memory together with a first node;
computing branch metrics of nodes linked to the first node and allocating the computed branch metrics in the stack;
computing branch metrics of nodes linked to a node whose branch metric is stored in the top of the stack; and
deleting a top stack entry from the stack, and reallocating the stack so that the computed branch metrics are included in the stack.

25. The stack algorithm method of claim 24, further comprising allocating the branch metrics in the stack in ascending order.

26. The stack algorithm method of claim 24, wherein the branch metrics of nodes linked to the node whose branch metric is stored in the top of the stack are repeatedly computed until a tree level of the top stack entry is equal to the number of branches.
